(19) United States
(12) Patent Application Publication
(10) Pub. No.: US 2005/0133915 A1
(43) Pub. Date: Jun. 23, 2005

(54) System and method for increasing the number of IO-s on a ball grid pattern

(75) Inventor: Masud Beroz, San Jose, CA (US)

Correspondence Address: STEVENS LAW GROUP, P.O. BOX 1667, SAN JOSE, CA, 95109, US

(73) Assignee: Tessera, Inc., San Jose, CA (US)

(21) Appl. No.: 11/013,965

(22) Filed: Dec. 15, 2004

Related U.S. Application Data
(60) Provisional application No. 60/532,345, filed on Dec. 23, 2003.

(51) Int. Cl. H01L 23/48

(52) U.S. Cl. 257/738

(57) ABSTRACT

A microelectronic circuit package having an integrated circuit chip bonded through an intermediate layer to a substrate. The integrated circuit chip has pads located on opposite surfaces, with the pads on one surface bonded to wire bond fingers for connection to the substrate, and pads on the opposite surface for connecting through vias in the intermediate layer to lead bonds on the substrate. The leads from the bond pads on the surface of the integrated circuit chip extend through a via located in at least one intermediate layer of the package to bond pads on the substrate. The opposite surface of the integrated circuit chip have wire bond leads from the wire bond pads on a surface of the integrated circuit chip to bond pads on the substrate.

### PRIOR APPLICATION

This application claims priority from U.S. Provisional Patent Application No. 60/532,345 filed Dec. 23, 2003.

### BACKGROUND

The invention is directed to a ball grid array package having pads on opposite major surfaces. The pads on one major surface are connected to a substrate, e.g., through vias (openings through insulating or dielectric material) to lead bonds, with the pads on the opposite major surface are connected through wire bonds to pads on the substrate.

Different types of electronic wire connections for electronic micro-chip packages are ubiquitous. In particular, wire bonding of connections to bond pads are required for making connections outside the microchip. The number of connections define the number of input and output connections (I/Os). As integrated circuit chips become more sophisticated with ever more functionality, the demand for I/Os increases, requiring more wire connections to the package. One conventional method includes wire bonding using wire bond fingers. The number of bond fingers can be increased (independent from the number of layers) to the extent fingers on the edge of the printed wiring board (PWB) or flex circuit can be formed. Such connections, however, do not provide adequate I/Os to a chip package. An alternative method is to provide what are known as micro ball grid array (micro-BGA) leads from a first metal layer. However, this method may not always provide adequate I/Os to a chip package either.

Therefore there exists a need for a new method of increasing I/Os to a chip package to keep up with the increasing demand. As will be seen, the invention does this in an elegant manner.

### SUMMARY

The increased I/O density is provided by combining two bonding structures, using wire bonds in combination with lead extensions from a metal layer of a chip package. The disclosed structure includes features of micro-LGA and micro-BGA packages. The invention uses metallurgy on one major surface of the integrated circuit chip as a routing to the bond fingers for wire bonds and full BGA real estate for metallurgy layers intended to be in contact with any of the next layers for microBGA lead bonds.

The microelectronic circuit package has an integrated circuit chip bonded through an intermediate layer to a substrate. The integrated circuit chip has pads located on opposite surfaces, with the pads on one surface bonded to wire bond fingers for connection to the substrate, and pads on the opposite surface for connecting through vias in the intermediate layer to lead bonds on the substrate. The leads from the bond pads on the surface of the integrated circuit chip extend through a via located in at least one intermediate layer of the package to bond pads on the substrate. The opposite surface of the integrated circuit chip have wire bond leads from the wire bond pads on a surface of the integrated circuit chip to bond pads on the substrate.

### THE FIGURES

Various aspects of our invention are illustrated in the Figures appended hereto.

FIG. 1 illustrates a partial cutaway side elevation of a package of the invention.

FIG. 2 illustrates a detailed micro BGA package with both type of bonds incorporated.

FIG. 3 illustrates pads at the center of the package connected through a via to the bottom side to provide an increase in IO density, per unit area.

### DESCRIPTION OF THE INVENTION

The invention is directed to increasing the I/O density in micro-LGA or micro-BGA package by combining two bonding structures, using wire bonds in combination with lead extensions from a metal layer of a chip package. The structure of our invention includes features of micro-LGA and micro-BGA packages. The invention uses metallurgy on one major surface of the integrated circuit chip as a routing to the bond fingers for wire bonds and full BGA real estate for metallurgy layers intended to be in contact with any of the next layers for microBGA lead bonds.

The invention is directed to increasing the number of I/O-s of an integrated circuit by providing current leads on opposite major surfaces or planes the integrated circuit chip.

The height of the total package, including the chip, the substrate, and intermediate layers, is significantly smaller than the comparable multilevel wire bonds for the same or even more I/Os. Using micro BGA leads and bond wires together provides more routing and bond finger density, using the least number of layers for the smallest possible foot print CSP.

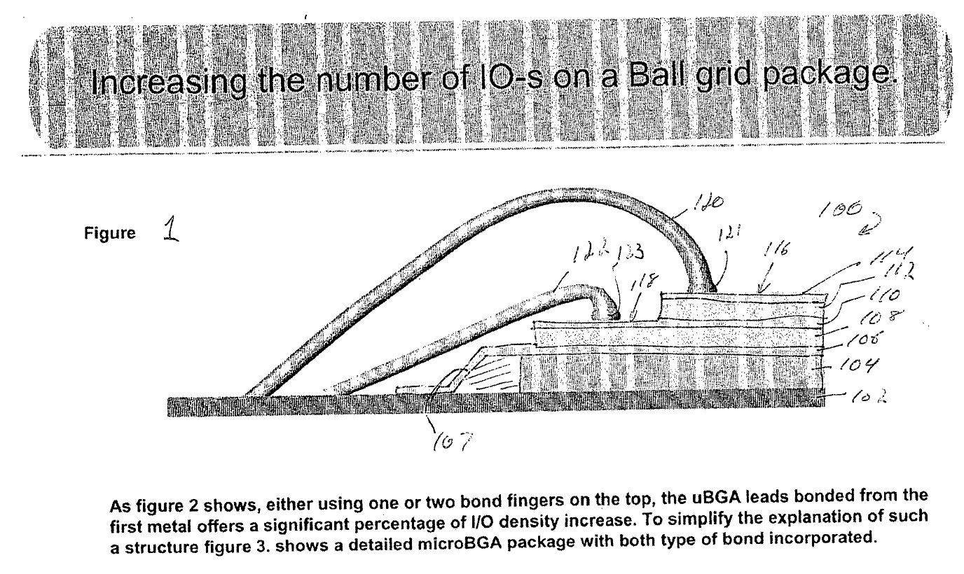

Referring to FIG. 1, a partial side cut-away view of a chip contact assembly 100 is illustrated. The assembly includes a printed wiring board (PWB) or the equivalent 102 for mounting a chip and related connectors to conductors mounted thereon. The assembly includes a substrate layer 104 having a first metal layer 106 formed thereon. According to the invention, this metal layer has a contact arm 107 for extending onto the surface of the PWB to make a conductive contact. Providing such a contact in addition to conventional contacts, allows an extra connection to the PWB that did not previously exist in conventional chip packages. A second layer 108, which may be a dielectric substrate or other material, is layered onto the first metal layer 106, and has a second metal layer 110 formed thereon. Another substrate layer 112 is mounted on the second metal layer, and has a third metal layer 114 mounted thereon. A conventional connection wire 120 is formed or otherwise mounted on the third metal layer surface 116 via connection 121, which may be a solder ball or other material for connecting the wire 120 to the surface 116. A second wire 122 is mounted on the second metal surface 118 of second metal layer 110 via connector 123, which also may be a solder ball or other connection.

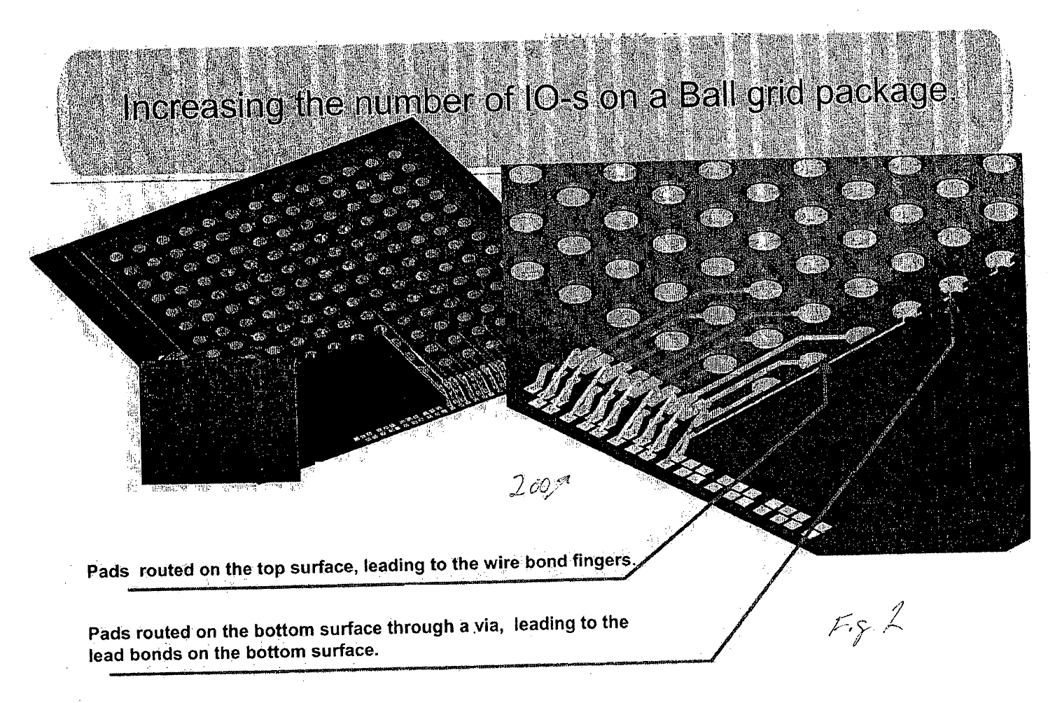

As FIG. 1 shows, either using one or two bond figures on the top, the micro-BGA leads bonded from the first metal offers a significant percentage of I/O density increase. This is illustrated in FIG. 2 which shows a detailed micro BGA package with both type of bonds incorporated.

Referring to FIG. 2, pads are shown routed on the top surface, leading to the wire bond fingers. Pads connected to the bottom layer of the chip have leads routed from the substrate through a via, leading to the lead bonds on the bottom surface.

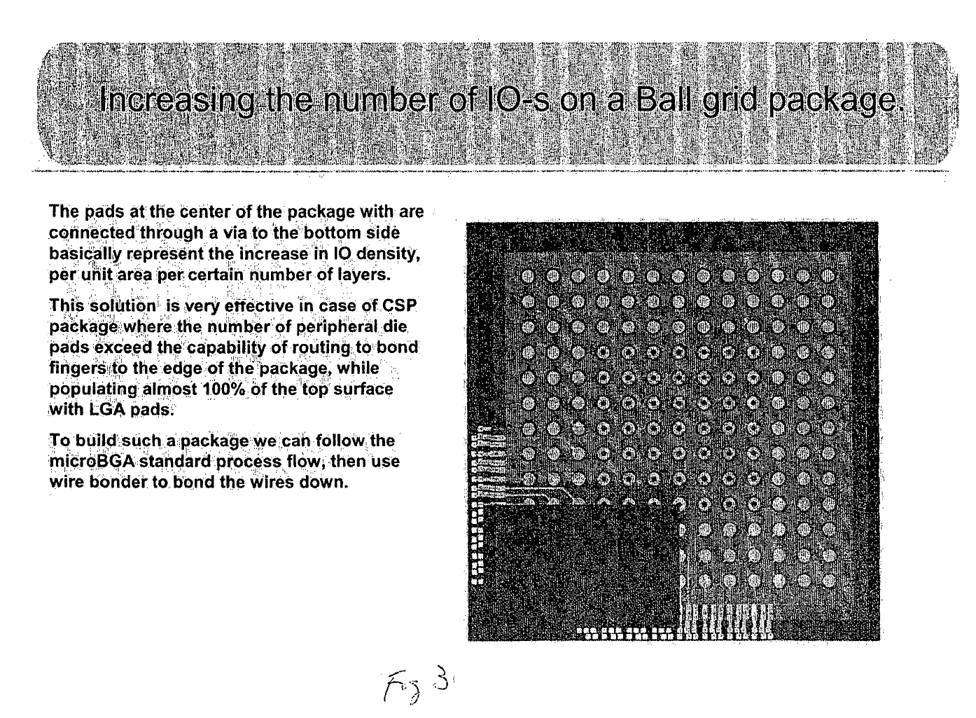

As shown in FIG. 3, the pads at the center of the package are connected through a via to the bottom side illustrate an increase in IO density, per unit area. This solution is very effective in case of CSP package where the number of peripheral die pads exceed the capability of routing to bond fingers to the edge of the package, while populating a major portion of the top surface with LGA pads. To build such a package we can follow the microBGA standard process flow, then wire bonder can be used to bond the wires down.

1. A ball grid array package having pads located on opposite surfaces thereof, with pads on one surface for bonding to wire bond fingers, and pads on the opposite surface connecting to lead bonds through vias.

2. A ball grid array according to claim 1, wherein the pads connected on the opposite surface utilizes upper mark layers as routing to the bond fingers for wire bond pads.

3. A microelectronic circuit package comprising an integrated circuit chip bonded through an intermediate layer to a substrate, said integrated circuit chip having pads located on opposite surfaces thereof, with pads on one surface for bonding to wire bond fingers for connection to said substrate, and pads on the opposite surface for connecting through vias in the intermediate layer to lead bonds on the substrate.

4. A microelectronic circuit package according to claim 3, further comprising leads from bond pads on a surface of the integrated circuit chip through a via located in at least one intermediate layer of the package to bond pads on the substrate.

5. A microelectronic circuit package according to claim 3, further comprising wire bond leads from wire bond pads on a surface of the integrated circuit chip to bond pads on the substrate.
